(19) United States
(12) Patent Application Publication
(10) Pub. No.: US 2009/0027144 A1
(43) Pub. Date: Jan. 29, 2009

(54) PRINTED WIRING BOARD

(75) Inventor: Shinichiro SAITO, Yokosuka-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/101,416

(22) Filed: Apr. 11, 2008

(30) Foreign Application Priority Data
Jul. 26, 2007 (JP) 2007-194762

(51) Int. Cl. H05K 1/00; H01P 3/08; H01P 3/14; H05K 3/00

(52) U.S. Cl. 333/238; 174/250; 174/254; 333/241; 29/829

(57) ABSTRACT

A printed wiring board includes a board made of insulator; a wiring pattern to transfer an electric signal which is made of patterned metallic conductor and formed on at least one of a main surface and a rear surface of the board; and an electric power layer formed on at least one of the main surface and the rear surface of the board; wherein the electric power layer includes a mechanism for controlling a characteristic impedance of the printed wiring board.

### CROSS-REFERENCE TO RELATED APPLICATIONS

This application is based upon and claims the benefit of priority from the prior Japanese Patent Application No. 2007-194762, filed on Jul. 26, 2007; the entire contents of which are incorporated herein by reference.

### BACKGROUND OF THE INVENTION

1. Field of the Invention

The present invention relates to a printed-wiring board particularly requiring high speed operation, large current rating and flexibility.

2. Description of the Related Art

A printed wiring board, on which (an) IC chip(s) with high speed operationality is (are) mounted and which requires large current rating, is available for various electronic devices such as a computer, a magneto-optical memory and a cellular phone. With a conventional printed-wiring board, a high frequency signal is transferred under a transfer mode using a micro strip line (MSL), a strip line (SL) or a coplanar waveguide (CPW). In the conventional printed-wiring board, the thickness of the board and the line width of the board are mainly designed so as to set the characteristic impedance of the board to a predetermined value. In this case, the characteristic impedance can be represented by the following equation (1):

$${Z}_{0} = \sqrt{\frac{R + jω L}{G + jω C}} \qquad ( 1 )$$

However, a flexible wiring board with large degree of freedom in structure is being employed as the electronic device is downsized. Since the thickness of the flexible wiring board is small so as to realize the flexibility thereof, it is difficult to design the characteristic impedance of the flexible wiring board.

On the other hand, such a design guide as controlling both of the current rating and the characteristic impedance, which are traded off with one another, is being expected as the current consumption is increased accompanied by the multifunction of the electronic device and the IC processing speed is increased. If the width of the wiring pattern of the flexible wiring board is decreased, the characteristic impedance of the flexible wiring board can be controlled. On the other hand, in this case, since the current rating of the flexible wiring board becomes small so that the wiring pattern of the flexible wiring board may be burned out. If the width of the wiring pattern of the flexible wiring board is increased, the characteristic impedance can not be appropriately controlled so that the effective electric power transfer efficiency may be decreased.

In this point of view, conventionally, the width of the wiring pattern is decreased so that the characteristic impedance can be appropriately controlled through the reduction of the current rating of the flexible wiring board. Alternatively, the width of the wiring pattern is increased so that the current rating can be maintained as designed under the compromise of the impedance matching. In the latter case, the impedance matching can be realized by mounting resistances for impedance matching in series and/or parallel to the driving IC or the load element (passive element, active element, optical device, etc.) in the vicinity of and/or apart from the driving IC or the load element. In this case, however, since electric power consumption is increased as a whole and much current is consumed at the resistances, the electric power is wasted.

In Reference 1, in the multilayered printed-wiring board which contains an MSL formed as the top layer thereof, the conductive pattern located below the MSL is partially removed so that the conductive pattern can not be superimposed with the MSL, and a ground pattern is formed as the bottom layer uniformly on the rear surface of the multilayered wiring board so that the ground pattern can be superimposed with the MSL, thereby controlling the characteristic impedance of the MSL, that is, the multilayered wiring board.

The technique disclosed in Reference 1, however, is effective for the multilayered wiring board with three or more, preferably, four or more conductive layers containing the MSL, but not effective for a flexible wiring board such as a double-sided printed wiring board which is configured such that the conductive patterns are formed on the main surface and the rear surface of the core board, respectively.

[Reference 1] JP-A 2006-74014 (KOKAI)

### BRIEF SUMMARY OF THE INVENTION

It is an object of the present invention, in view of the above-described problems, to provide a printed-wiring board which can conduct the control of the characteristic impedance independent of the number of conductive pattern composing the printed-wiring board.

In order to achieve the above object, an aspect of the present invention relates to a printed wiring board, including: a board made of insulator; a wiring pattern to transfer an electric signal which is made of patterned metallic conductor and formed on at least one of a main surface and a rear surface of the board; and an electric power layer formed on at least one of the main surface and the rear surface of the board; wherein the electric power layer includes a mechanism for controlling a characteristic impedance of the printed wiring board.

According to the aspect of the present invention, the electric power layer of the printed wiring board includes the mechanism for controlling the characteristic impedance of the printed wiring board. Therefore, the characteristic impedance of the printed wiring board can be easily controlled only by operating the mechanism even though the width of the wiring pattern is not controlled as in the past. As a result, the design of the wiring pattern in view of the current rating is not required so that the degree of freedom in design of the wiring pattern can be developed. For example, there is no advantage that the current rating of the wiring pattern, that is, the printed wiring board is increased even though the width of the wiring pattern is decreased in view of impedance matching.

In an embodiment, the mechanism is a trench which is formed below and/or above the wiring pattern throughout the electric power layer over a long direction of the wiring pattern. In this case, the characteristic impedance of the printed wiring board can be controlled by adjusting the width of the trench. Concretely, the width of the trench is controlled in view of the shape and size of the wiring pattern and the intended characteristic impedance of the printed wiring board. For example, the width of the trench is set within a range of 0.1 W to 3 W when the width of the wiring pattern is defined as numeral character “W”.

In the embodiment, it is desired that the center of the wiring pattern in the width direction thereof is matched with the center of the trench in the width direction thereof. In this case, the characteristic impedance of the printed wiring board can be controlled effectively and absolutely by adjusting the width of the trench.

The aspects of the present invention as described above can be applied for any printed wiring board. However, the aspects can be applied more effectively and absolutely for a flexible printed wiring board by making the board of heat resistance resin base.

The aspects of the present invention can be applied for a printed wiring board which is configured such that the wiring pattern is formed on the main surface of the board and the electric power layer is formed on the rear surface of the board, thereby including a double-sided wiring structure. Moreover, the aspects can be applied for a printed wiring board which is configured such that the electric power layer includes a first electric power layer and a second electric power layer so that the first electric power layer is formed on the main surface of the board and the second electric power layer is formed on the rear surface of the board, thereby including a double-sided wiring structure.

The flexible printed wiring board and the double-sided printed wiring board include no multilayered conductive pattern. As disclosed in Reference 1, therefore, if the multilayered conductive pattern is formed so that the conductive pattern located below the MSL (wiring pattern) is partially removed and the conductive pattern can not be superimposed with the MSL, the manufacturing cost of the printed wiring board is increased and the flexibility of the printed wiring board is reduced because the printed wiring board includes the multilayered conductive pattern. On the other hand, according to the aspects of the present invention, the characteristic impedance of the printed wiring board can be effectively controlled.

The characteristics of the flexible printed wiring board may be independent from or combined with the characteristics of the double-sided printed wiring board. For example, a double-sided flexible printed wiring board may be provided.

The present invention is not limited to the flexible printed wiring board and the double-sided printed wiring board, but may be applied to any printed wiring board. For example, a rigid printed wiring board and a multilayered printed wiring board may be included within the scope of the present invention.

As the double-sided printed wiring board may be exemplified a micro strip line (MSL) type printed wiring board, a strip line (SL) type printed wiring board and a coplanar waveguide type printed wiring board.

According to the aspect of the present invention can be provided a printed-wiring board which can conduct the control of the characteristic impedance independent of the number of conductive pattern composing the printed-wiring board.

### BRIEF DESCRIPTION OF THE SEVERAL VIEWS OF THE DRAWINGS

FIG. 1 is a perspective view illustrating an embodiment of the printed-wiring board according to the present invention.

FIG. 2 is a side view of the printed-wiring board in FIG. 1, as viewed from the direction designated by the arrow “A”.

FIG. 3 is a perspective view of another embodiment of the printed-wiring board according to the present invention.

FIG. 4 is a perspective view illustrating still another embodiment of the printed-wiring board according to the present invention.

### DETAILED DESCRIPTION OF THE INVENTION

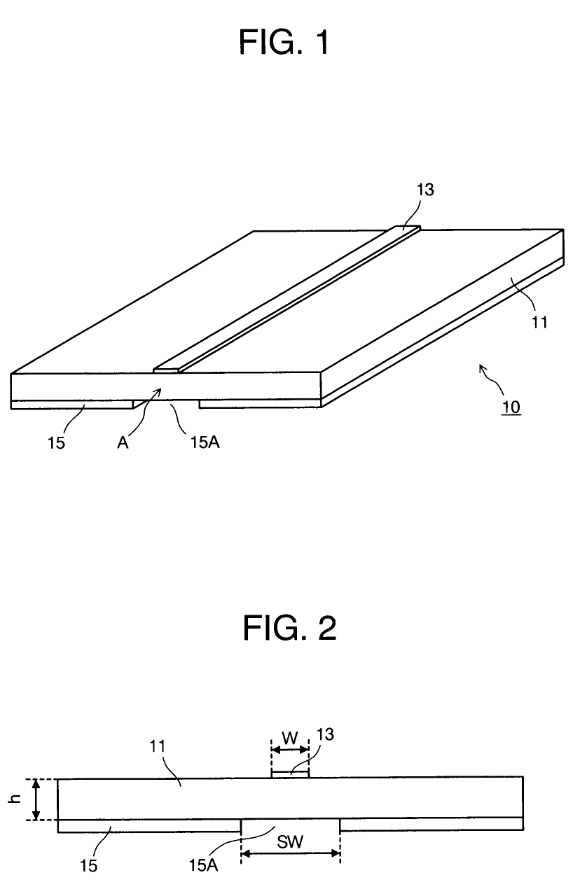

Hereinafter, the present invention will be described in detail with reference to the drawings. FIG. 1 is a perspective view illustrating an embodiment of the printed-wiring board according to the present invention. FIG. 2 is a side view of the printed-wiring board in FIG. 1, as viewed from the direction designated by the arrow “A”.

The printed-wiring board 10 illustrated in FIG. 1 includes aboard 11 made of insulator, a metallic conductor (wiring pattern) 13 to transfer (a) microwave electric signal(s) which is formed on the main surface of the board 11 and an electric power layer 15 formed on the rear surface of the board 11, thereby constituting a double-sided printed wiring board with a double-sided wiring structure. The electric power layer 15 is maintained a standard electric potential or shifted slightly from the standard electric potential so that the potential shift from the standard electric potential can be small enough to set the characteristic impedance of the electric power layer 15 negligible within a signal frequency range of the wiring pattern 13 (e.g., to tithe or less of the transfer impedance). In other words, the electric power layer 15 may be shifted from the standard electric potential only if the potential shift from the standard electric potential can be small enough to set the characteristic impedance of the electric power layer 15 negligible within a signal frequency range of the wiring pattern 13 (e.g., to tithe or less of the transfer impedance).

In this embodiment, the wiring pattern 13 is formed as a micro strip line (MSL).

As shown in FIGS. 1 and 2, a trench 15A is formed throughout the electric power layer 15 over the long direction of the wiring pattern 13 directly below the wiring pattern 13. The trench 15A functions as an impedance controller for the wiring pattern 13, that is, the printed-wiring board 10. Concretely, the characteristic impedance of the printed-wiring board 10 is entirely changed by controlling the width SW of the trench 15A. Therefore, the desired characteristic impedance can be realized for the printed-wiring board 10 by appropriately controlling the width of the trench 15A commensurate with the shape and size of the wiring pattern 13.

As shown in FIG. 2, it is desired that the center of the wiring pattern 13 in the width direction thereof is matched with the center of the trench 15A in the width direction thereof. If not matched, the characteristic impedance of the printed-wiring board 10 may not be effectively and efficiently changed by appropriately controlling the width SW of the trench 15A.

Suppose that the width of the wiring pattern 13 is defined as numeral character “W”, the width SW of the trench 15A is preferably set within a range of 0.1 W to 3 W, more preferably within a range of 0.1 W to 1 W. If the width SW of the trench 15A is less than 0.1 W, the characteristic impedance of the printed-wiring board 10 may not be changed sufficiently in dependence with the size and shape of the wiring pattern 13. Namely, if the width SW of the trench 15A is less than 0.1 W, the characteristic impedance of the printed-wiring board 10 may not be changed sufficiently in comparison with a printed-wiring board 10 with no trench. Similarly, if the width SW of the trench 15A is more than 3 W, the characteristic impedance of the printed-wiring board 10 may not be changed sufficiently in dependence with the size and shape of the wiring pattern 13. The reason will be described below.

In this embodiment, since the printed wiring board 10 is formed as the double-sided wiring structure, the wiring pattern 13 is disposed in the vicinity of the electric power layer 15 via the board 11 which is located at the center of the wiring board 10. Therefore, since the wiring pattern 13 is electrically interfered with the electric power layer 15 strongly so that the electric interference between the wiring pattern 13 and the electric power layer 15 is changed remarkably when the configuration (shape and size) of the wiring pattern 13 and/or the electric power layer 15 is changed slightly. As a result, since the electric interference between the wiring pattern 13 and the electric power layer 15 is changed remarkably by forming the trench 15A at the electric power layer 15 so that the capacitance formed between the wiring pattern 13 and the electric power layer 15 is also changed remarkably, the characteristic impedance of the printed wiring board 10 can be effectively and efficiently changed.

In this point of view, if the width SW of the trench 15A is set more than 3 W, since the electric interference between the wiring pattern 13 and the electric power layer 15 becomes extremely small or negligible, the capacitance formed between the wiring pattern 13 and the electric power layer 15 can not almost be changed so that the characteristic impedance of the printed wiring board 10 can be effectively and efficiently changed.

Referring to the technical principle as described above, the thickness of the board 11 is set preferably to 200 μm or less, more preferably to 50 μm or less, particularly preferably to 12.5 μm or less. In this case, if the board 11 is made of a material as described below, the board 11 can be flexible so that the printed wiring board 10 can be a flexible printed wiring board.

The lower limited value of the thickness of the board 11 may be set to several μm in view of the dielectric breakdown strength of the board 11 dependent on the constituent material.

In the conventional technique as disclosed in Reference 1, a plurality of conductive patterns, located below the MSL, are partially removed so that the removal of the conductive patterns can be set larger than the width of the MSL and thus, the MSL can not be electrically interfered with the conductive patterns, thereby conducting the impedance control. In contrast, in the present embodiment (invention), the wiring pattern 13 is electrically interfered with the electric power layer 15 by intent, thereby conducting the control. As a result, the technical idea of Reference 1 is quite different from the technical idea of the present embodiment (invention).

The board 11 may be made of a given insulator. As the insulator can be exemplified polyester, polyimide or glass epoxy based flexible material, polysulfone, polyetherimide or polyether thermoplastic resin and liquid crystal.

In this embodiment (invention), a rigid printed wiring board is not excluded. In this case, paper (e.g., FR-1, FR-2, XXXpc, Xpc, FR-3), glass (e.g., FR-4, G-10, FR-5, G-11, GPY), epoxy or polyester based composite (CEM-1, CEM-3, FR-6), alumina, alumina nitride or silicon carbide low temperature sintered ceramic material can be exemplified.

The wiring pattern 13 and the electric power layer 15 may be made of e.g., Cu, Ag, Au, aluminum or an alloy thereof.

Not shown in FIGS. 1 and 2, adhesive layers may be formed between the board 11 and the wiring pattern 13 and/or between the board 11 and the electric power layer 15. Then, cover layers (containing respective adhesive layers thereof) may be formed on the main surface and the rear surface of the board 11 over the wiring pattern 11, the trench 15A and the electric power layer 15. Moreover, reinforcing boards may be formed on the respective cover layers.

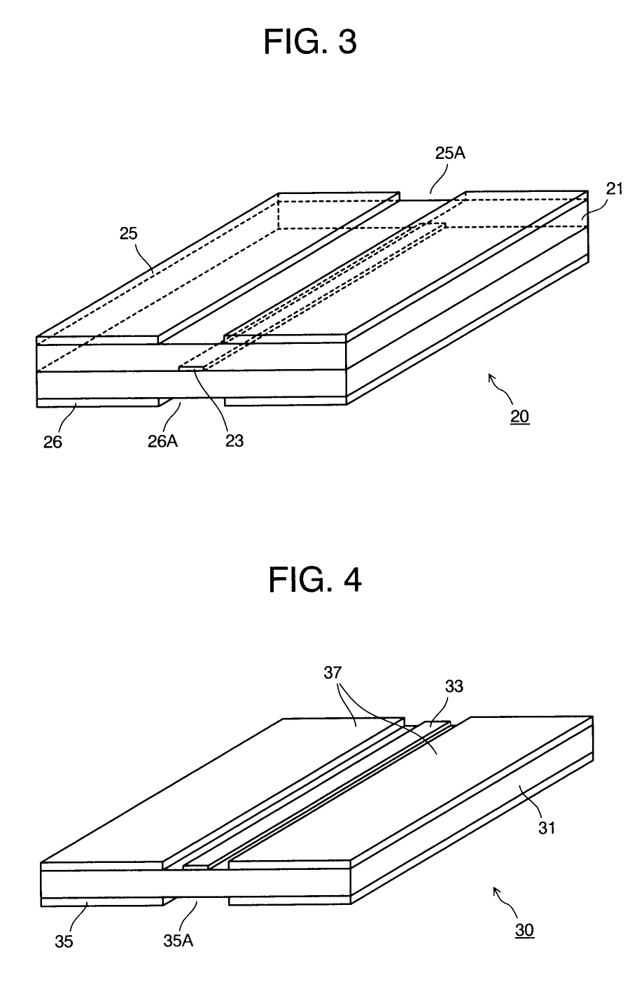

FIG. 3 is a perspective view of another embodiment of the printed-wiring board according to the present invention. The printed-wiring board 20 illustrated in FIG. 3 includes a board 21 made of insulator, a metallic conductor (wiring pattern) 23 to transfer (a) microwave electric signal(s) which is formed in the board 21 in parallel with the main surface and the rear surface of the board 21, a first electric power layer 25 and a second electric power layer 26 which are formed on the main surface and the rear surface of the board 21, respectively. The wiring pattern 23 is disposed at the center area of the board 11 in the thickness direction of the board 21 and is elongated along the long direction of the board 21. The first electric power layer 25 and the second electric power layer 26 are maintained a standard electric potential or shifted slightly from the standard electric potential so that the potential shift from the standard electric potential can be small enough to set the characteristic impedances of the electric power layers 25 and 26 negligible within a signal frequency range of the wiring pattern 23 (e.g., to tithe or less of the transfer impedance). In other words, the electric power layers 25 and 26 may be shifted from the standard electric potential only if the potential shift from the standard electric potential can be small enough to set the characteristic impedances of the electric power layers 25 and 26 negligible within a signal frequency range of the wiring pattern 23 (e.g., to tithe or less of the transfer impedance).

In this embodiment, the wiring pattern 13 is formed as a strip line (SL).

As shown in FIG. 3, in this embodiment, a trench 25A is formed throughout the first electric power layer 25 over the long direction of the wiring pattern 23 directly above the wiring pattern 23 and a trench 26A is formed throughout the second electric power layer 26 over the long direction of the wiring pattern 23 directly below the wiring pattern 23. The trenches 25A and 26A function as impedance controllers for the wiring pattern 23, that is, the printed-wiring board 20.

Concretely, the characteristic impedance of the printed-wiring board 20 is entirely changed by controlling the widths of the trenches 25A and 26A. Therefore, the desired characteristic impedance can be realized for the printed-wiring board 20 by appropriately controlling the widths of the trenches 25A and 26A commensurate with the shape and size of the wiring pattern 23.

In this case, it is also desired that the center of the wiring pattern 23 in the width direction thereof is matched with the centers of the trenches 25A and 26A in the width direction thereof. If not matched, the characteristic impedance of the printed-wiring board 20 may not be effectively and efficiently changed by appropriately controlling the widths of the trenches 25A and 26A.

Suppose that the width of the wiring pattern 23 is defined as numeral character “W”, the widths of the trenches 25A and 26A are preferably set within a range of 0.1 W to 3 W, more preferably within a range of 0.1 W to 1 W. If the widths of the trenches 25A and 26A are less than 0.1 W, the characteristic impedance of the printed-wiring board 20 may not be changed sufficiently in dependence with the size and shape of the wiring pattern 23. Similarly, if the widths of the trenches 25A and 26A are more than 3 W, the characteristic impedance of the printed-wiring board 20 may not be changed sufficiently in dependence with the size and shape of the wiring pattern 23.

In this embodiment, the trenches 25A and 26A are formed at the first electric power layer 25 and the second electric power layer 26, respectively. However, if either of the trenches 25A and 26A is formed at the first electric power layer 25 or the second electric power layer 26, the function/effect of the present invention, that is, the characteristic impedance of the printed wiring board 20 can be appropriately controlled. If both of the trenches 25A and 26A are formed at the first electric power layer 25 or the second electric power layer 26 as described in this embodiment, the characteristic impedance of the printed wiring board 20 can be controlled more effectively and efficiently.

The thickness of the board 21 is set preferably to 200 μm or less, more preferably to 50 μm or less, particularly preferably to 12.5 μm or less. In this case, if the board 21 is made of a material as described below, the board 21 can be flexible so that the printed wiring board 20 can be a flexible printed wiring board.

The lower limited value of the thickness of the board 21 may be set to several μm in view of the dielectric breakdown strength of the board 21 dependent on the constituent material.

The board 21 may be made of a given insulator. As the insulator can be exemplified polyester, polyimide or glass epoxy based flexible material, polysulfone, polyetherimide or polyether thermoplastic resin and liquid crystal.

In this embodiment (invention), a rigid printed wiring board is not excluded. In this case, paper (e.g., FR-1, FR-2, XXXpc, Xpc, FR-3), glass (e.g., FR-4, G-10, FR-5, G-11, GPY), epoxy or polyester based composite (CEM-1, CEM-3, FR-6), alumina, alumina nitride or silicon carbide low temperature sintered ceramic material can be exemplified.

The wiring pattern 23, the first electric power layer 25 and the second electric power layer 26 may be made of e.g., Cu, Ag, Au, aluminum or an alloy thereof.

Not shown in FIG. 3, adhesive layers may be formed between the board 21 and the wiring pattern 23, between the board 21 and the first electric power layer 25 and/or between the board 21 and the second electric power layer 26. Then, cover layers (containing respective adhesive layers thereof) may be formed on the main surface and the rear surface of the board 11 over the wiring pattern 21, the trenches 25A, 26A and the electric power layers 25, 26. Moreover, reinforcing boards may be formed on the respective cover layers.

FIG. 4 is a perspective view of still another embodiment of the printed-wiring board according to the present invention. The printed-wiring board 30 illustrated in FIG. 4 includes a board 31 made of insulator, a metallic conductor 33 to transfer (a) microwave electric signal(s) which is formed on the board 31, and an electric power layer 35. The electric power layer 35 functions as a reference electrode for the metallic conductor 33 and is maintained constant electric potential for the metallic conductor 33 so that the microwave electric signal(s) can be transferred under good condition. The electric power layer 35 may be electrically grounded, but may be maintained a predetermined electric potential only if the microwave electric signal(s) can be transferred in the metallic conductor 33.

In this embodiment, a pair of grounded electrode layers 37 are formed on both sides of the metallic conductor 33 so as to sandwich the metallic conductor 33. In this case, the metallic conductor 33 and the grounded electrode layers 37 constitute the wiring pattern as a coplaner waveguide (CPW).

The grounded electrode layers 37 are maintained a standard electric potential or shifted slightly from the standard electric potential so that the potential shift from the standard electric potential can be small enough to set the characteristic impedance of the grounded electrode layers 37 negligible within a signal frequency range of the metallic conductor 33 (i.e., wiring pattern), for example, to tithe or less of the transfer impedance. In other words, the electric power layer 35 and the grounded electrode layers 37 may be shifted from the respective standard electric potential only if the potential shift from the standard electric potentials can be small enough to set the characteristic impedances of the electric power layer 35 and the grounded electrode layers 37 negligible within a signal frequency range of the wiring pattern (e.g., to tithe or less of the transfer impedance).

As shown in FIG. 4, in this embodiment, a trench 35A is formed throughout the electric power layer 35 over the long direction of the metallic conductor 33 directly below the metallic conductor 33 over the long direction of the metallic conductor 33. The trench 35A functions as an impedance controller for the metallic conductor (wiring pattern) 33, that is, the printed-wiring board 30. Concretely, the characteristic impedance of the printed-wiring board 30 is entirely changed by controlling the width of the trench 35A. Therefore, the desired characteristic impedance can be realized for the printed-wiring board 30 by appropriately controlling the width of the trench 35A commensurate with the shape and size of the metallic conductor (wiring pattern) 33.

In this case, it is also desired that the center of the metallic conductor 33 in the width direction thereof is matched with the centers of the trench 35A in the width direction thereof. If not matched, the characteristic impedance of the printed-wiring board 30 may not be effectively and efficiently changed by appropriately controlling the width of the trench 35A.

Suppose that the width of the metallic conductor 33 is defined as numeral character “W”, the width of the trench 35A is preferably set within a range of 0.1 W to 3 W, more preferably within a range of 0.1 W to 1 W. If the width of the trench 35A is less than 0.1 W, the characteristic impedance of the printed-wiring board 30 may not be changed sufficiently in dependence with the size and shape of the wiring pattern containing the metallic conductor 33. Similarly, if the width of the trench 35A is more than 3 W, the characteristic impedance of the printed-wiring board 30 may not be changed sufficiently in dependence with the size and shape of the wiring pattern containing the metallic conductor 33.

The board 31 is preferably configured as the boards 11 and 21 as described above. Namely, the thickness of the board 31 is set preferably to 200 μm or less, more preferably to 50 μm or less, particularly preferably to 12.5 μm or less. The lower limited value of the thickness of the board 31 may be set to several μm in view of the dielectric breakdown strength of the board 31 dependent on the constituent material.

The board 31 may be made of a given insulator. As the insulator can be exemplified flexible material such as polyester, polyimide or glass epoxy based flexible material, polysulfone, polyetherimide or polyether thermoplastic resin and liquid crystal or rigid material such as paper (e.g., FR-1, FR-2, XXXpc, Xpc, FR-3), glass (e.g., FR-4, G-10, FR-5, G-11, GPY), epoxy or polyester based composite (CEM-1, CEM-3, FR-6), alumina, alumina nitride and silicon carbide low temperature sintered ceramic material.

The metallic conductor 33, the electric power layer 35 and the grounded electrode layers 37 may be made of e.g., Cu, Ag, Au, aluminum or an alloy thereof.

Not shown in FIG. 4, adhesive layers may be formed between the board 31 and the metallic conductor 33, the grounded electrode layers 37 (that is, wiring pattern) and/or between the board 31 and the electric power layer 35. Then, cover layers (containing respective adhesive layers thereof) may be formed on the main surface and the rear surface of the board 31 over the metallic conductor 33 and the grounded electrode layers 37 (i.e., wiring pattern), the trench 35A and the electric power layer 35. Moreover, (Example)

In this Example, the printed wiring board 10 as shown in FIGS. 1 and 2 was fabricated so that the change in characteristic impedance of the printed wiring board 10 was examined with the change in width SW of the trench 15A. In this case, the width W of the wiring pattern (MSL) 13 was set to 100 μm and the thickness of the board 11 was set to 12.5 μm. As a result, it was confirmed the characteristic impedance of the printed wiring board 10 is changed within a range of 20 to 150Ω by changing the width SW of the trench 15A within a range of 10 to 300 μm. Herein, the characteristic impedance of a printed wiring board with no trench was 18Ω.

As a result, it was confirmed that if a trench is formed at an electric power layer of a printed wiring board throughout the electric power layer and then, the width of the trench is changed appropriately, the characteristic impedance of the printed wiring board can be controlled.

Although the present invention was described in detail with reference to the above examples, this invention is not limited to the above disclosure and every kind of variation and modification may be made without departing from the scope of the present invention.

What is claimed is:

1. A printed wiring board, comprising:
a board made of insulator;
a wiring pattern to transfer an electric signal which is made of patterned metallic conductor and formed on at least one of a main surface and a rear surface of said board; and
an electric power layer formed on at least one of said main surface and said rear surface of said board;
wherein said electric power layer includes a mechanism for controlling a characteristic impedance of said printed wiring board.

2. The printed wiring board as set forth in claim 1,
wherein said mechanism is a trench which is formed below and/or above said wiring pattern throughout said electric power layer over a long direction of said wiring pattern.

3. The printed wiring board as set forth in claim 1,
wherein a center of said wiring pattern in a width direction thereof is matched with a center of said trench in a width direction thereof.

4. The printed wiring board as set forth in claim 1,
wherein said width of said trench is set within a range of 0.1 W to 3 W when said width of said wiring pattern is defined as numeral character “W”.

5. The printed wiring board as set forth in claim 1,
wherein said board is made of heat resistance resin base so that said printed wiring board can be a flexible printed wiring board.

6. The printed wiring board as set forth in claim 5,
wherein said heat resistance resin base contains at least one selected from the group consisting of polyester resin, polyimide resin, polysulfone resin and polyether resin.

7. The printed wiring board as set forth in claim 1,
wherein a thickness of said board is set to 200 μm or less.

8. The printed wiring board as set forth in claim 1,
wherein said wiring pattern is formed on said main surface of said board and said electric power layer is formed on said rear surface of said board so that said printed wiring board can include a double-sided wiring structure.

9. The printed wiring pattern as set forth in claim 8,
wherein said wiring pattern is formed as a micro strip line (MSL) on said main surface of said board.

10. The printed wiring board as set forth in claim 8,
wherein said wiring pattern comprises a metallic conductor and a pair of grounded electrode layers which are formed along a long direction of said metallic conductor so as to sandwich said metallic conductor, thereby constituting a coplanar waveguide (CPW).

11. The printed wiring board as set forth in claim 1,
wherein said electric power layer includes a first electric power layer and a second electric power layer so that said first electric power layer is formed on said main surface of said board and said second electric power layer is formed on said rear surface of said board and said printed wiring board includes a double-sided wiring structure.

12. The printed wiring board as set forth in claim 11,
wherein said wiring pattern is formed as a strip line (SL) in said board.

13. A method for controlling a characteristic impedance of a printed wiring board including a board made of insulator; a wiring pattern to transfer an electric signal which is made of patterned metallic conductor and formed on at least one of a main surface and a rear surface of said board; and an electric power layer formed on at least one of said main surface and said rear surface of said board; comprising:
forming a trench below and/or above said wiring pattern throughout said electric power layer over a long direction of said wiring pattern so that a characteristic impedance of said printed wiring board is controlled.

14. The method as set forth in claim 13,
further comprising:
matching a center of said wiring pattern in a width direction thereof with a center of said trench in a width direction thereof.

15. The method as set forth in claim 13,
further comprising:
setting said width of said trench within a range of 0.1 W to 3 W when said width of said wiring pattern is defined as numeral character “W”.
